(19) United States
(12) Patent Application Publication
(10) Pub. No.: US 2011/0207264 A1
(43) Pub. Date: Aug. 25, 2011

(54) MANUFACTURING METHOD OF SEMICONDUCTOR DEVICE

(75) Inventors: Manabu TOMISAKA, Nagoya-city (JP); Akira Tai, Okazaki-city (JP); Kazuo Akamatsu, Okazaki-city (JP); Yutaka Fukuda, Kariya-city (JP); Yoshiko Fukuda, Kariya-city (JP); Yuji Fukuda, Osaka-city (JP); Mika Ootsuki, Kariya-city (JP); Mayu Fukuda, Kariya-city (JP)

(73) Assignee: DENSO CORPORATION, Kariya-city (JP)

(21) Appl. No.: 12/905,395

(22) Filed: Oct. 15, 2010

(30) Foreign Application Priority Data
Oct. 19, 2009 (JP) 2009-240729
Sep. 9, 2010 (JP) 2010-202191

(51) Int. Cl. H01L 21/56

(52) U.S. Cl. 438/114; 257/E21.502

(57) ABSTRACT

A method of manufacturing a semiconductor device includes cutting a part of a resin insulating layer formed on a surface of a semiconductor substrate with a cutting tool. The cutting the part of the resin insulating layer includes cutting a portion of the resin insulating layer that has a surface on which a metal layer is disposed. The cutting the portion of the resin insulating layer is performed in such a manner that, in a stress distribution inside the resin insulating layer along an edge portion of the cutting tool and a peripheral portion of the edge portion, a width at 90% of a maximum value is not more than 1.3 μm.

### CROSS REFERENCE TO RELATED APPLICATIONS

The present application is based on and claims priority to Japanese Patent Applications No. 2009-240729 filed on Oct. 19, 2009 and No. 2010-202191 filed on Sep. 9, 2010, the contents of which are incorporated in their entirety herein by reference.

### BACKGROUND OF THE INVENTION

1. Field of the Invention

The present invention relates to a manufacturing method of a semiconductor device including cutting a part of a resin insulating layer formed on a surface of a semiconductor substrate with a cutting tool.

2. Description of the Related Art

Conventionally, various methods of manufacturing a semiconductor device that include a cutting process of removing a part of a resin insulating layer formed on a surface of a semiconductor substrate with a cutting tool are disclosed.

In a semiconductor device disclosed in the patent document 1 (JP-A-2006-186304), an underlying electrode is formed on a surface of a semiconductor substrate in which an element is formed, and a protective layer made of polyimide (corresponding to a resin insulating layer) is formed on the surface of the semiconductor substrate so as to cover the underlying electrode. The protective layer has an opening portion so that a connection portion of the underlying electrode that is coupled with a metal electrode is exposed. The metal layer is formed on a surface of the connection portion of the underlying electrode and a sidewall of the opening portion of the protective layer. In a manufacturing method of the above-described semiconductor device, a metal layer is formed on the surface of the connection portion of the underlying electrode and a surface of the protective layer (i.e., an upper surface and the sidewall of the opening portion), and the protective layer is cut on a cutting surface that is set between the upper surface of the protective layer and the surface of the connection portion of the underlying electrode so that the metal layer has a predetermined pattern.

In a method disclosed in the patent document 2 (WO 2004/061935 A1 which correspond to US 2009/0186425 A1), a resist mask (corresponding to a resin insulating layer) having a predetermined bump pattern is formed on a surface of a semiconductor substrate, and bumps made of gold (Au) are formed so as to fill the bump pattern in the resist mask. Surface layers of the bumps and the resist mask are cut with a cutting tool so that the surfaces of the bumps and the resist mask are continuously flat. Then, the resist mask is removed, for example, by an ashing process. Accordingly, the bumps having the same height and having uniformly-planarized upper surfaces are formed.

In a manufacturing method disclosed in the patent document 3 (JP-A-2006-148062 which corresponds to US 2006/0084253 A1), after a resin layer (corresponding to a resin insulating layer) is formed on a semiconductor substrate, a surface portion of the resin layer is cut so that a ten-point average roughness of the surface of the resin layer is from 0.5 μm to 5 μm. That is, unevenness is intentionally provided on the cutting surface. Then, a seed layer is formed on the cutting surface of the resin layer, and a plating layer is formed on the seed layer. Accordingly, an adhesion between the resin layer and the seed layer can be secured.

A metal layer and a resin insulation layer have different rigidities. Thus, in a case where a part of an insulating layer on which a metal layer is disposed is cut, a tensile stress applied to the resin insulating layer in the vicinity of an edge portion of the cutting tool is large compared with a case where only the resin insulating layer is cut. Thus, a cutting surface of the resin insulating layer located under the metal layer may be easily torn. In other words, a crack may be generated in the cutting surface of the resin insulating layer.

In a method of manufacturing a semiconductor device disclosed in the patent document 4 (JP-A-2008-218823 which corresponds to US 2008/0217771 A1), a cutting tool having a first edge portion and a second edge portion at an edge of a front surface of the cutting tool is used. The first edge portion is formed from an edge of the front surface forward in a feed direction of the cutting tool, and the second edge portion is formed from the edge of the front surface backward in the feed direction. A part of a protective layer (corresponding to a resin insulating layer) on which a metal layer is disposed is cut with the first edge portion. Then, after the cutting tool moves a predetermined pitch in the feed direction, a part of the protective layer that is exposed by cutting with the first edge portion is cut with the second edge portion.

The patent documents 1 and 2 fail to disclose conditions of cutting with a cutting tool. Thus, a crack may be generated in a cutting surface of the resin insulating layer during cutting the resin insulating layer. If a crack is generated, the crack may grow when the resin insulating layer is applied with stress due to a temperature change during a thermal endurance test or an actual use. Thus, it is difficult for the resin insulating layer to have a predetermined insulating property. In other words, if a crack is generated, an insulating reliability may be reduced. Thus, if a crack is generated in the resin insulating layer, it is difficult to secure insulating properties of the underlying electrode and the element.

In the method disclosed in the patent document 3, the unevenness is intentionally provided on the surface of the resin insulating layer. Thus, a crack may be generated in the cutting surface of the resin insulating layer during cutting the resin insulating layer. In addition, because the cutting surface is rough, a thickness of the resin insulating layer is not uniform, and a predetermined insulating property may be not secured at a part of the insulating layer.

In the method disclosed in the patent document 4, a surface roughness of the resin insulating layer can be reduced compared with a case where the resin insulating layer is cut only with the first edge portion and is not cut with the second edge portion. However, a crack may be generated in the cutting surface of the resin insulating layer when only the resin insulating layer is cut with the second edge portion.

### SUMMARY OF THE INVENTION

In view of the foregoing problems, it is an object of the present invention to provide a manufacturing method of a semiconductor device that can restrict a generation of a crack in a cutting surface of a resin insulating layer.

According to a first aspect of the present invention, a method of manufacturing a semiconductor device includes cutting a part of a resin insulating layer formed on a surface of a semiconductor substrate with a cutting tool. The cutting the part of the resin insulating layer includes cutting a portion of the resin insulating layer that has a surface on which a metal layer is disposed. The cutting the portion of the resin insulating layer is performed in such a manner that, in a stress distribution inside the resin insulating layer along an edge portion of the cutting tool and a peripheral portion of the edge portion, a width at 90% of a maximum value is not more than 1.3 μm.

In the method according to the first aspect of the present invention, when the portion of the resin insulating layer that has the surface on which the metal layer is disposed is cut, a generation of a crack in a cutting surface of the resin insulating layer can be restricted.

According to a second aspect of the present invention, a method of manufacturing a semiconductor device includes cutting a part of a resin insulating layer formed on a surface of a semiconductor substrate with a cutting tool. The cutting the part of the resin insulating layer includes cutting a portion of the resin insulating layer that has a surface exposed to an outside. The cutting the portion of the resin insulating layer is performed in such a manner that, in a stress distribution inside the resin insulating layer along an edge portion of the cutting tool and a peripheral portion of the edge portion, a width at 90% of a maximum value is not more than 0.06 μm.

In the method according to the second aspect of the present invention, when the portion of the resin insulating layer that has the surface exposed to the outside is cut, a generation of a crack in a cutting surface of the resin insulating layer can be restricted.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1 is a cross-sectional view of a semiconductor device according to a first embodiment of the present invention;

FIG. 2A to FIG. 2C are cross-sectional views showing processes in a manufacturing method of the semiconductor device according to the first embodiment;

FIG. 3 is a graph showing a stress strain curve of a resin A;

FIG. 4A is a diagram showing a crack generated in the rear of a cutting edge of a cutting tool and FIG. 4B is a diagram showing a crack generated in front of a cutting edge of the cutting tool;

FIG. 5 is a diagram showing a stress distribution and a stress direction in a resin insulating layer in a case where the resin insulating layer is made of the resin A and in a case where the resin insulating layer is made of a resin B;

FIG. 6 is a diagram showing measurement positions of stress values in the resin insulating layer;

FIG. 7 is a graph showing analysis results of the stress values;

FIG. 8A is a diagram showing a simplified analysis result in the case where the resin insulating layer is made of the resin A and FIG. 8B is a diagram showing a simplified analysis result in the case where the resin insulating layer is made of the resin B;

FIG. 9 is a graph showing a relationship between an extension of resin and a width at 90% of the maximum value;

FIG. 10 is a cross-sectional view showing a cutting thickness;

FIG. 11 is a graph showing a relationship between the cutting thickness and a width at 90% of the maximum value;

FIG. 12A is a plan view of a shaving when the cutting thickness is not less than 7 μm, and FIG. 12B is a plan view of a shaving when the cutting thickness is less than 7 μm;

FIG. 13 is a diagram for explaining a curvature radius of an edge portion of a cutting tool in a cutting direction;

FIG. 14 is a graph showing a relationship between the curvature radius and a width at 90% of the maximum value;

FIG. 15 is a cross-sectional view showing a semiconductor device according to a modification;

FIG. 16A and FIG. 16B are cross-sectional views showing processes in a manufacturing method of a semiconductor device according to a second embodiment of the present invention;

FIG. 17 is a graph showing a relationship between an extension of resin and a width at 90% of the maximum value;

FIG. 18 is a diagram showing physical properties and appearance evaluation results of resin insulating layers made of different resin materials;

FIG. 19 is a graph showing a relationship between a cutting thickness and a width at 90% of the maximum value;

FIG. 20 is a graph showing a relationship between a curvature radius of an edge portion and a width at 90% of the maximum value;

FIG. 21 is a cross-sectional view showing a state where a metal layer and a resin insulating layer are cut with a cutting tool;

FIG. 22 is a cross-sectional view showing a predetermined pitch and a cutting state of the resin insulating layer when the cutting tool is moved by the predetermined pitch in a pitch feed direction;

FIG. 23 is a cross-sectional view showing a cutting process according to a modification;

FIG. 24 is a cross-sectional view showing a front rake θ of a cutting tool; and

FIG. 25 is a cross-sectional view showing a semiconductor device according to another modification.

### DETAILED DESCRIPTION OF THE PREFERRED EMBODIMENTS

### First Embodiment

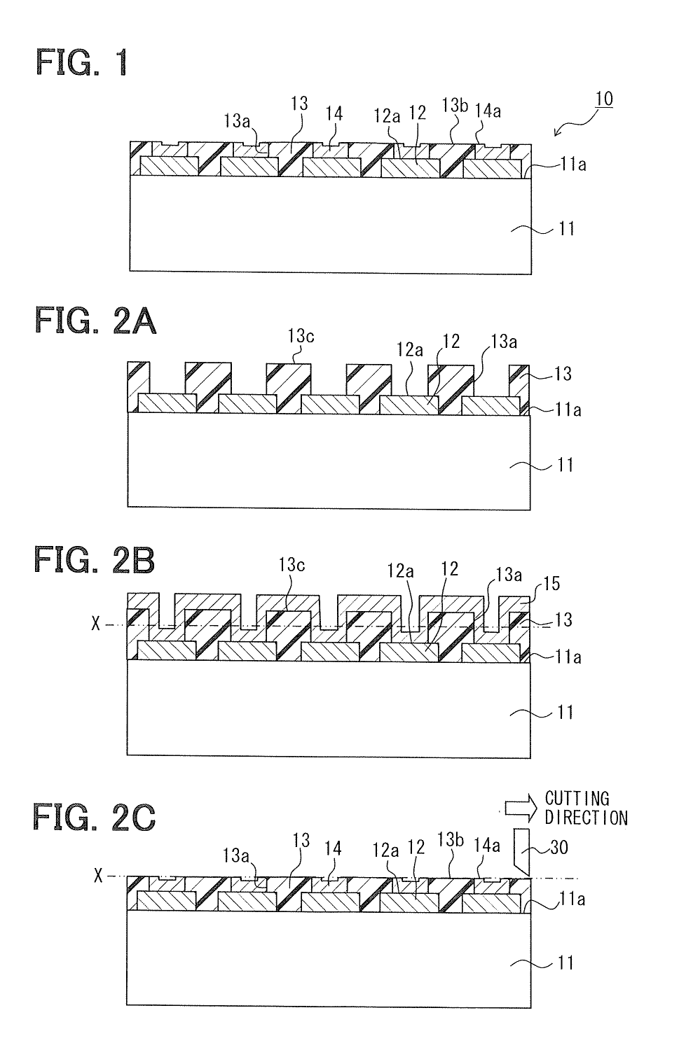

A structure of a semiconductor device 10 according to a first embodiment of the present invention will be described with reference to FIG. 1. In addition, a method of manufacturing the semiconductor device 10 will be described with reference to FIG. 2A to FIG. 2C. In each figure, a part of the semiconductor device 10 is enlarged and another part of the semiconductor device 10 is omitted for the sake of explanation. A symbol X in FIG. 2B and FIG. 20 indicates a cutting surface with a cutting tool. For making a position clear, the cutting surface X is also shown in FIG. 2B.

In the manufacturing method of the semiconductor device 10 according to the present embodiment, (i) a portion of a resin insulating layer that has a surface on which a metal layer is disposed is cut in such a manner that, in a stress distribution inside the resin insulating layer along an edge portion of the cutting tool and a peripheral portion of the edge portion, a width at 90% of a maximum value is not more than 1.3 μm. In the following description, vicinity of the edge portion includes the edge portion and the peripheral portion of the edge portion. In order to satisfy the point (i), (ii) a resin insulating layer having an extension of more than 0% and not more than 80% is used, (iii) a cutting tool whose edge portion has a curvature radius of not more than 0.25 μm in a cutting direction is used, and (iv) a portion of the resin insulating layer on which the metal layer is disposed is cut by a cutting thickness of not less than 0.5 μm and not more than 12 μm. The structure and the manufacturing method of the semiconductor device 10 other than the above-described points are similar to those disclosed in the patent document 4. Therefore, a detailed description will be omitted.

As shown in FIG. 1, the semiconductor device 10 includes a semiconductor substrate 11, a plurality of underlying electrodes 12, a resin insulating layer 13, and a plurality of metal electrodes 14. The semiconductor substrate 11 has a front surface 11a. The underlying electrodes 12 are electrodes of a semiconductor element formed in the semiconductor substrate 11 and are disposed on the front surface 11a. The resin insulating layer 13 covers a part of the front surface 11a and the underlying electrodes 12. The resin insulating layer 13 has a plurality of opening portions 13a. The metal electrodes 14 are coupled with connection portions 12a of the respective underlying electrodes 12 though the respective opening portions 13a.

The semiconductor element formed in the semiconductor substrate 11 may be any element. In the present embodiment, the semiconductor substrate 11 is made of silicon, and a vertical insulated gate bipolar transistor (vertical IGBT) as a power transistor element is formed in the semiconductor substrate 11. In the vertical IGBT, electric current flows in a thickness direction of the semiconductor substrate 11. As a power transistor element, a vertical metal-oxide semiconductor field-effect transistor (vertical MOSFET) may also be formed in the semiconductor substrate 11. The power transistor element including a gate can be used, for example, as a power device configurating an inverter for driving a load. The semiconductor device 10 including the semiconductor substrate 11 can be used as a power card. The semiconductor element is not limited to a vertical element and may also be a horizontal element such as a laterally diffused metal-oxide semiconductor transistor element (LDMOS transistor element) and a bipolar transistor element.

The underlying electrodes 12 are coupled with the semiconductor element. The underlying electrodes 12 may be made of, for example, aluminum-base material such as aluminum, an alloy of aluminum and silicon, and an alloy of aluminum, silicon, and copper. The underlying electrodes 12 are coupled with an emitter or a gate of the IGBT formed in the semiconductor substrate 11. All the underlying electrodes 12 shown in FIG. 1 are coupled with the emitter. Also in the following description, only underlying electrodes coupled with emitter are illustrated. In the semiconductor device 10, a large electric current flows to the IGBT as the power transistor element. Thus, a thickness of the underlying electrodes 12 is set to a few μm (for example, 5 μm) so that electric current which is uniformed in a planar direction flows in the thickness direction.

The extension of the resin insulating layer 13 is more than 0% and not more than 80%. The resin insulating layer 13 covers portions of the surfaces of the underlying electrodes 12 other than the connection portions 12a and the front surface 11a of the semiconductor substrate 11 so as to secure electric insulation (dielectric strength voltage) of the underlying electrodes 12 and the semiconductor element formed in the semiconductor substrate 11. The resin insulating layer 13 has a plurality of opening portions 13a so that the surfaces of the connection portions 12a of the underlying electrodes 12 are exposed to an outside of the resin insulating layer 13. The surfaces of the connection portions 12a of the underlying electrodes 12 are depressed with respect to a cutting surface 13b of the resin insulating layer 13. The cutting surface 13b of the resin insulating layer 13 is formed when the resin insulating layer 13 is treated with a cutting process. In the cutting surface 13b, a crack or a tear is not generated. For example, the resin insulating layer 13 is made of polyimide resin and has a thickness of from a few μm to 20 μm.

The metal electrodes 14 are electrically coupled with the semiconductor element through the underlying electrodes 12. In addition, the metal electrodes 14 are electrically coupled with an external device through members such as solder and wires. In the semiconductor device 10 shown in FIG. 1, the metal electrodes 14 are formed only in the opening portions 13a. The metal electrodes 14 cover the connection portions 12a of the underlying electrodes 12 and sidewalls of the opening portions 13a of the resin insulating layer 13. Upper surfaces 14a of the metal electrodes 14 are located on the same plane with the upper surface of the resin insulating layer 13. For example, the metal electrodes 14 include a titanium (Ti) layer, a nickel (Ni) layer, and a gold (Au) layer stacked in this order from a side of the underlying electrodes 12. The metal electrodes 14 may also include a Ni layer and a Au layer stacked in this order from the side of the underlying electrode 12. The metal electrodes 14 may also be a single metal layer. The metal electrodes 14 may also include a NiV layer instead of a Ni layer.

A manufacturing method of the semiconductor device 10 will be described below. During a process shown in FIG. 2A, a semiconductor substrate 11 in which the semiconductor element (not shown) is formed is prepared. In the present embodiment, the semiconductor substrate 11 is made of silicon and the IGBT is formed in the semiconductor substrate 11. On a rear surface of the semiconductor substrate 11, a rear-surface side electrode (collector electrode) is formed. A rear-surface side region (collector region) and the rear-surface side electrode of the IGBT are formed before front-surface side electrodes including the underlying electrodes 12 and the metal electrodes 14 are formed so that an exposed portion of the rear surface of a wafer is not polluted by material (Au) of the metal electrodes 14 when the metal electrodes 14 are formed.

Next, on the front surface 11a of the semiconductor substrate 11, an Al—Si layer is formed, for example, by sputtering. The Al—Si layer is treated with a patterning process with photolithography and the underlying electrodes 12 are formed. The resin insulating layer 13 is formed on the whole area of the front surface 11a of the semiconductor substrate 11, for example, by a spin coat method so as to cover the underlying electrodes 12. The resin insulating layer 13 is made of polyimide resin and has a thickness of 10 μm. The extension of the resin insulating layer 13 is more than 0% and not more than 80%. For example, the extension of the resin insulating layer 13 is 60%. Then, the opening portions 13a are provided at predetermined portions of the resin insulating layer 13 so that the connection portions 12a of the underlying electrodes 12 are exposed. The opening portions 13a extending from a surface 13c of the resin insulating layer 13 to the underlying electrodes 12 are provided by a photolithography method. By using resin for the resin insulating layer 13, the underlying electrodes 12 can be covered appropriately. In a state where the opening portions 13a are provided, the connection portions 12a of the underlying electrodes 12 are depressed with respect to the surface 13c of the resin insulating layer 13.

During a process shown in FIG. 2B, a metal layer 15 is formed so as to cover the connection portions 12a of the underlying electrodes 12, the surface 13c of the resin insulating layer 13, and the sidewalls of the opening portions 13a of the resin insulating layer 13. In the present embodiment, the metal layer 15 is formed by stacking a Ti layer, a NiV layer, and a Au layer in order. Vanadium in the NiV layer can function as a barrier layer for solder.

During a process shown in FIG. 2C, the whole area of the front surface 11a of the semiconductor substrate 11 is cut on a predetermined cutting surface X with a cutting tool 30. In the present embodiment, the cutting tool 30 is a straight tool. An edge portion 30a (cutting edge) of the cutting tool 30 has a curvature radius of not more than 0.25 μm in the cutting direction. The resin insulating layer 13 is cut with the cutting tool 30 by a cutting thickness of not less than 0.5 μm and not more than 12 μm. A relative rate of the cutting tool 30 and the semiconductor device 10 is not less than 5 m/s (for example, 20 m/s), and a pitch P (see FIG. 22) of the cutting process is 70 μm. The pitch P can be controlled with a rotation number of a spindle and a feed rate of a work piece. For example, when the rotation number of the spindle is 2000 rpm and the feed rate of the work piece is 2.3 mm/s, the pitch P can be about 70 μm. A height accuracy of the cutting tool 30 with respect to the metal layer 15 is not more than 0.1 μm. By using carbonated water as a lubricant, a change in device properties due to static electricity is restricted, a temperature rise due to cutting is restricted, and a shaving is removed.

In the cutting process, the cutting surface X is set between the surface 13c of the resin insulating layer 13 and the surface (connection portions 12a) of the underlying electrodes 12 in the thickness direction of the semiconductor substrate 11. The metal layer 15 above the surface 13c of the resin insulating layer 13 is removed with a surface portion of the resin insulating layer 13 located above the cutting surface X so that the metal layer 15 remains only inside the opening portions 13a and the portion of the metal layer 15 located inside the opening portions 13a form the metal electrodes 14. Thus, the metal electrodes 14 cover the connection portions 12a of the underlying electrodes 12 and the sidewalls of the opening portions 13a of the resin insulating layer 13. In the cutting process, a waviness restriction method disclosed in JP-A-2009-49356 can be used. In the waviness restriction method, a surface shape measuring device and a deforming device including a piezoelectric actuator are used for restricting a waviness of the semiconductor substrate 11. Thus, the cutting surface X can be formed at a predetermined position.

Reasons of above-described points (i)-(iv) adopted in the present embodiment will be described below.

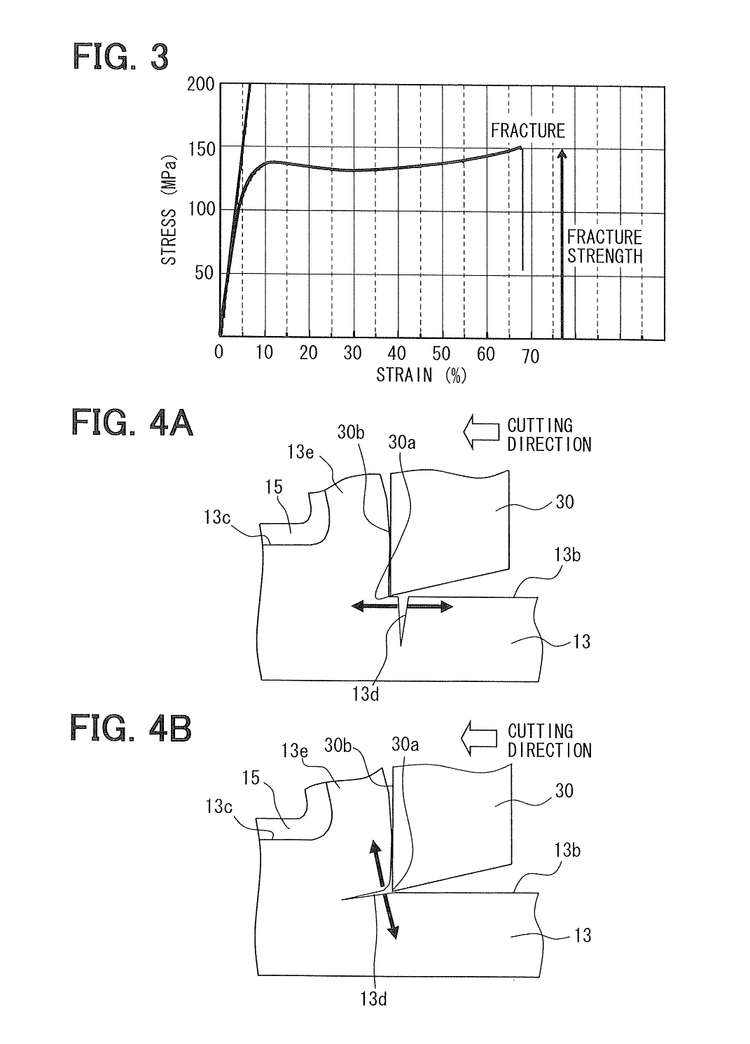

FIG. 3 is a stress strain curve of a resin A (PIX3400). When a strain (deformation) of resin increases, first, an elastic deformation occurs due to a change in a bonding angle, a rotation, and an expansion of a chemical bond of atoms that form molecules. In the elastic deformation region (for example, when a strain is less than 5% in FIG. 3), a stress increases substantially linearly in accordance with the strain. When the strain of resin further increases, an entwinement of molecular chains unfastens, a disconnection of the molecular chains occurs, and micro viscous flow occurs. At this time, a plastic deformation of resin occurs. However, the stress does not change drastically. When the strain further increases in a plastic deformation region, and the stress reaches a fracture strength (also called a cutting strength or a fracture stress), a fracture occurs in the resin. The strain at a time when the facture occurs (the maximum deformation just before the facture of the resin occurs) is a so-called extension. The extension can be expressed as a ratio with respect to an original length. In this way, when the stress is greater than the fracture strength, a fracture, that is, a crack is generated.

When the portion of the resin insulating layer 13 that has the surface 13c on which the metal layer 15 is disposed is cut with the cutting tool 30, a crack 13d shown in FIG. 4A and a crack 13d shown in FIG. 4B may be generated. The crack 13d shown in FIG. 4A is generated in the rear of the cutting edge when a tensile stress generated at a portion of the resin insulating layer 13 just behind the edge portion 30a of the cutting tool 30 exceeds the fracture strength. The crack 13d on the rear of the cutting edge is generated in the cutting surface 13b.

The crack 13d shown in FIG. 4B is generated in front of the cutting edge when a tensile stress generated at a portion of the resin insulating layer 13 in front of the edge portion 30a of the cutting tool 30 exceeds the fracture strength, and a crack grows forward the cutting edge. If the crack 13d in front of the cutting edge is not removed by cutting with the cutting tool 30, a crack originated from the crack 13d remains on the cutting surface 13b. In every case, a crack generated in the cutting surface 13b of the resin insulating layer 13 is caused when a tensile stress generated in the resin insulating layer 13 exceeds the fracture strength. The cutting tool 30 has a front surface 30b. By cutting the resin insulating layer 13 with the cutting tool 30, a shaving 13e is generated as shown in FIG. 4A and FIG. 4B.

The inventors of the present inventions focused on a stress distribution in the resin insulating layer 13 and three parameters that affect the stress in the resin insulating layer 13 when the resin insulating layer 13 is cut, and the inventors carried out the following study. The three parameters are the extension of the resin insulating layer 13, the cutting thickness of the resin insulating layer 13, and the curvature radius of the edge portion 30a of the cutting tool 30 in the cutting direction. In the study, a cutting tool DFS-8910 made by DISCO is used with a diamond tool as the cutting tool 30, and the resin insulating layer 13 on which the metal layer 15 is disposed is cut from a side adjacent to the surface 13c. The resin insulating layer 13 has a thickness of 23 μm, and the metal layer 15 made of Ni and having a thickness of 3.5 μm is disposed on the surface 13c of the resin insulating layer 13.

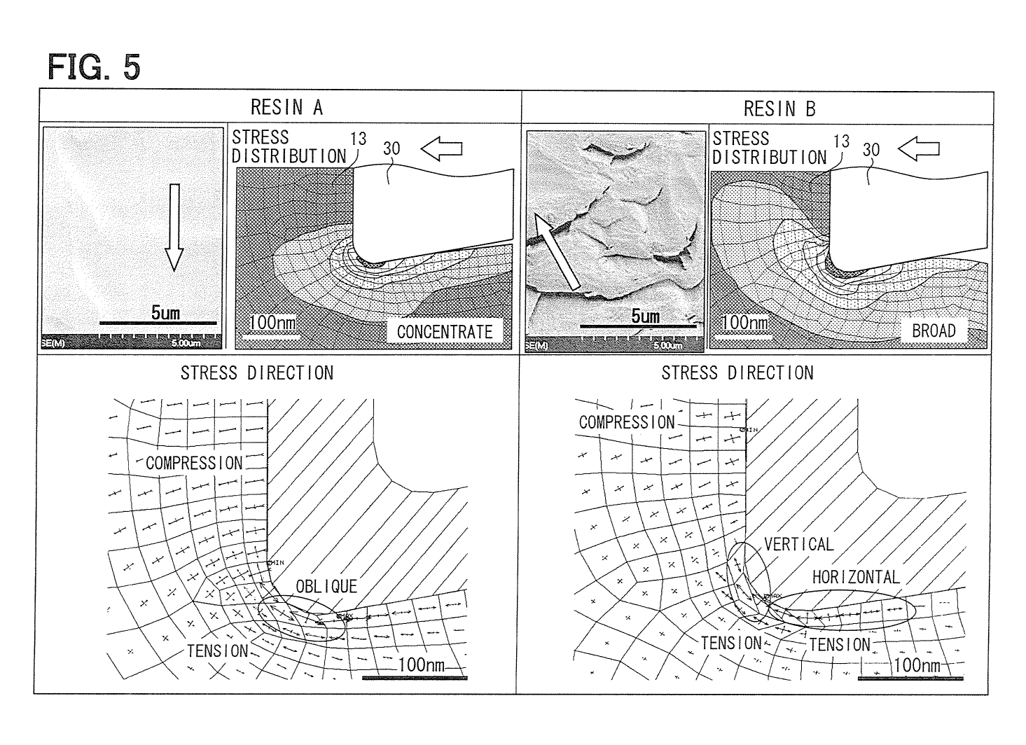

First, the stress distribution in the resin insulating layer 13 will be described with reference to FIG. 5 to FIG. 8B. The inventors analyzed the stress distribution and a stress direction in the resin insulating layer 13 in the vicinity of the edge portion 30a during the cutting process based on an actual measurement of external force during the cutting process, an actual measurement of physical properties (stress strain curve) of resins, and an analysis by computer aided engineering (CAE).

In the study, the resin insulating layer 13 is made of the resin A or a resin B. The resin A is PIX3400, which is polyimide available from HD MicroSystems. The resin B is HD8820, which is polyimide available from HD MicroSystems. Regarding properties of the resin A and the resin B, see FIG. 18. In FIG. 5, a SEM image (enlarged image) of the cutting surface 13b, an analysis result of a stress distribution in the resin insulating layer 13, and a stress direction in the resin insulting layer 13 during the cutting process are shown in a case where the resin insulating layer 13 is made of the resin A and in a case where the insulating layer 13 is made of the resin B. In the case where the resin insulating layer 13 is made of the resin A, a tensile stress is concentrated at the edge portion 30a and a crack is not generated in the cutting surface 13b. In the case where the resin insulating layer 13 is made of the resin B, a tensile stress is generated in a large area in the vicinity of the edge portion 30a and cracks (tears) are generated in the cutting surface 13b.

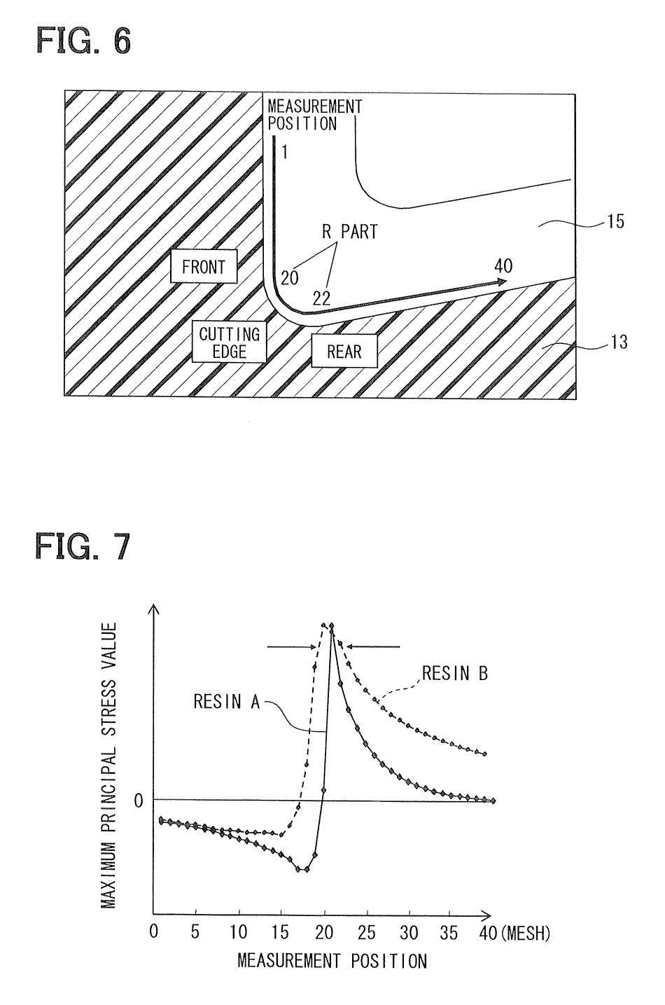

A relationship between mesh positions 1-40 shown in FIG. 6 and the maximum principal stress values are shown in FIG. 7. In other words, FIG. 7 shows the stress distribution inside the resin insulating layer 13 along the edge portion 30a of the cutting tool 30 and the peripheral portion of the edge portion 30a. The mesh positions 20-22 correspond to the edge portion 30a (R part) of the cutting tool 30. In the case where the resin insulating layer 13 is made of the resin A, as shown by the solid line in FIG. 7, the maximum principal stress value becomes the maximum value at the edge portion 30a of the cutting tool 30 (cutting edge) and the stress value drastically decreases in front of the and in the rear of the cutting edge. A width at 90% of the maximum value (a width shown by arrows in FIG. 7) is not more than 1.3 μm.

In the case where the resin insulating layer 13 is made of the resin B, as shown by the dashed line in FIG. 7, the maximum principal stress value becomes the maximum value in front of the cutting edge compared with the case where the resin insulating layer 13 is made of the resin A. In addition, the maximum principal stress is high in a large area, and a width at 90% of the maximum value is more than 1.3 μm.

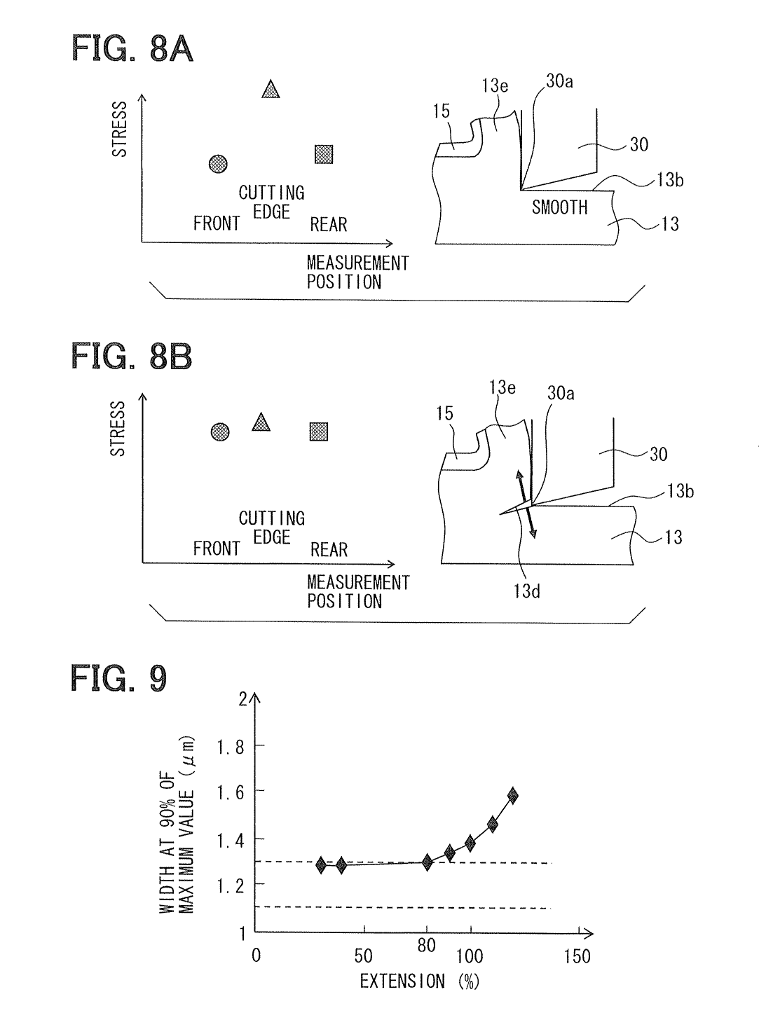

In the resin insulating layer 13 made of the resin A, because the tensile stress exceeds the fracture strength only at the portion corresponding to the edge portion 30a of the cutting tool 30 (cutting edge) as shown in FIG. 8A, a crack is not generated in the cutting surface 13b of the resin insulating layer 13. In the resin insulating layer 13 made of the resin B, the tensile stress close to the fracture strength is generated not only at the portion corresponding to the edge portion 30a of the cutting tool 30 (cutting edge) but also in the peripheral portion of the edge portion 30a, that is, in front of the cutting edge and in the rear of the cutting edge. Thus, a crack 13d is generated, for example, in front of the cutting edge.

Also in cases where the resin insulating layer 13 is made of resins other than the resin A and the resin B, a crack 13d is generated in the cutting surface 13b in a case where, in the stress distribution inside the resin insulating layer 13 along the edge portion 30a of the cutting tool 30 and the peripheral portion of the edge portion 30a, the width at 90% of the maximum value is more than 1.3 μm when a portion of the resin insulating layer 13 on which the metal layer 15 is disposed is cut. Even in cases where the cutting thickness of the resin insulating layer 13 and the curvature radius of the edge portion 30a of the cutting tool 30 in the cutting direction are changed, a crack is generated when the width at 90% of the maximum value is more than 1.3 μm in the stress distribution inside the resin insulating layer 13 along the edge portion 30a of the cutting tool 30 and the peripheral portion of the edge portion 30a.

A relationship between the width at 90% of the maximum value in the stress distribution and a generation of a crack 13d can be considered as follows. When the width at 90% of the maximum value is more than 1.3 μm, the resin insulating layer 13 is extended by the edge portion 30a of the cutting tool 30 and a strain increases. Thus, in the resin insulating layer 13, a plastic deformation region (a region applied with the tensile stress) distributes in a large area around the edge portion 30a, and a crack 13d is generated at a potion where the tensile stress exceeds the fracture strength. When the width at 90% of the maximum value is not more than 1.3 μm, the strain due to extension is small and the plastic deformation region concentrates in a small region around the edge portion 30a of the cutting tool 30. Thus, a generation of a crack 13d in the cutting surface 13b can be restricted.

In the method according to the present embodiment, the resin insulating layer 13 is cut in such a manner that, in the stress distribution of the resin insulating layer 13 along the edge portion 30a of the cutting tool 30 and the peripheral portion of the edge portion 30a, the width at 90% of the maximum value is not more than 1.3 μm. Thus, when the portion of the resin insulating layer 13 on which the metal layer 15 is disposed is cut, a generation of a crack 13d in the cutting surface 13b of the resin insulating layer 13 can be restricted. Therefore, in the resin insulating layer 13 after the cutting process, a deterioration of the insulation reliability can be restricted.

A lower limit of the width at 90% of the maximum value depends on manufacturing limits such as a lower limit of the curvature radius of the edge portion 30a of the cutting tool 30 and a lower limit of the cutting thickness. In the present condition, the lower limit of the width at 90% of the maximum value is about 1.1 μm. In view of the above-described point, the resin insulating layer 13 may be cut in such a manner that the width at 90% of the maximum value is within a range from 1.1 μm to 1.3 μm.

A relationship between the extension of the resin insulating layer 13 and a generation of a crack 13d can be considered as follows. FIG. 9 is a diagram showing a simulation result of a relationship between an extension of resin and the width at 90% of the maximum value. In FIG. 9, the upper dashed line indicates the upper limit 1.3 μm, and the lower dashed line indicates the lower limit 1.1 μm. As shown in FIG. 9, when the extension of rein is 80%, the width at 90% of the maximum value is 1.3 μm, and when the extension is not more than 80%, the width at 90% of the maximum value is substantially constant with respect to the extension. When the extension is more than 80%, the width at 90% of the maximum value increases with the extension and the width at 90% of the maximum value becomes a value more than 1.3 μm.

In this way, when the extension of the resin insulating layer 13 is more than 80%, because the extension is large, the resin insulating layer 13 is extended without fracturing even when the strain increases. While the resin insulating layer 13 is extended, the stress increases little as shown in FIG. 3, and the plastic deformation region distributes in a large area in the vicinity of the edge portion 30a of the cutting tool 30. Then, a crack 13d is generated at a portion where the stress exceeds the fracture strength, that is, at a portion in the rear of the cutting edge or at a portion in front of the cutting edge as shown in FIG. 8B. However, when the resin insulating layer 13 is made of resin that has an extension more than 0% and not more than 80%, the extension of the resin insulating layer 13 is small. Thus, the plastic deformation region does not distribute in a large area and a fracture occurs at the edge portion 30a of the cutting tool 30. Because the cutting process proceeds in a state where a deformation of resin at the peripheral portion of the edge portion 30a is small, a generation of a crack 13d in the cutting surface 13b can be restricted.

The inventors evaluated existence or nonexistence of a crack (tear) in cutting surfaces of various resins having different extensions with a scanning electron microscope (SEM) although images of SEM are not shown. As the result of the evaluation, it is found that a crack 13d is not generated in the cutting surfaces of resins having an extension of not more than 80%, and a crack 13d is generated in the cutting surfaces of resins having an extension of more than 80%.

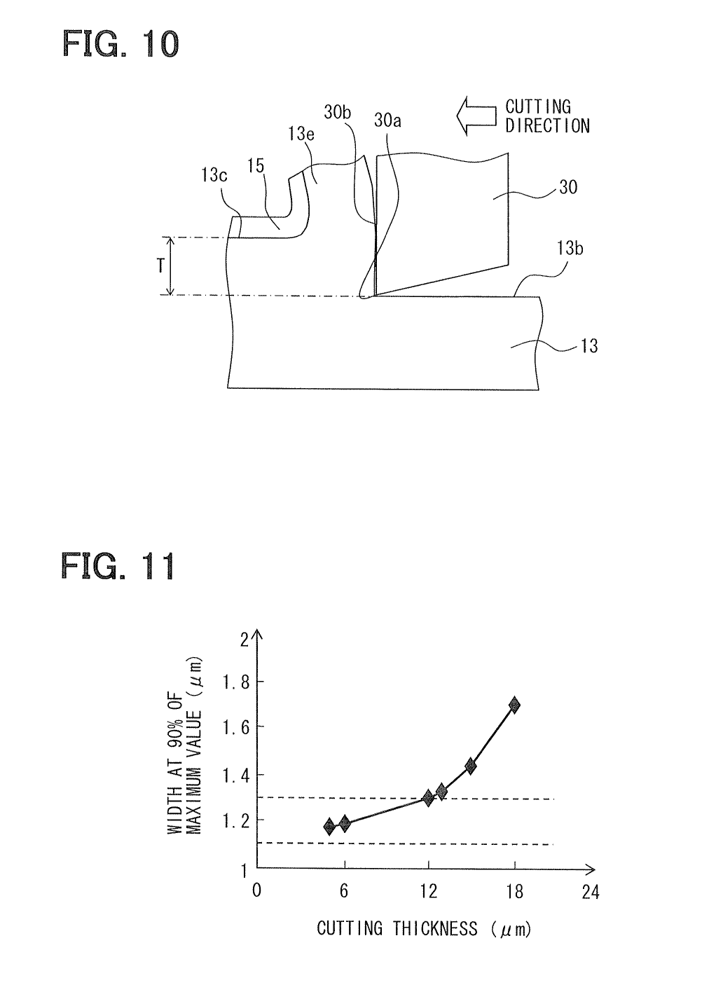

Next, a cutting thickness T of the resin insulating layer 13 with the cutting tool 30 will be described below. FIG. 10 is a cross-sectional view showing the cutting thickness T of the resin insulating layer 13. The white arrow in FIG. 10 indicates the cutting direction of the cutting tool 30. FIG. 11 is a diagram showing a simulation result of a relationship between the cutting thickness T and the width at 90% of the maximum value. In FIG. 11, the upper dashed line indicates the upper limit 1.3 μm, and the lower dashed line indicates the lower limit 1.1 μm.

According to the study by the inventors, it is preferred that the cutting thickness T shown in FIG. 10 is set to be not less than 0.5 μm and not more than 12 μm. The resin insulating layer 13 elastically deforms by a thrust force (a force pressing the cutting tool 30 downward) during the cutting process. Thus, when the cutting thickness T is less than 0.5 μm, the thickness of the resin insulating layer 13 is so thin that the edge portion 30a of the cutting tool 30 does not bit the resin insulating layer 13, and the cutting thickness T may be not stable. However, when the cutting thickness T is not less than 0.5 μm, the cutting thickness T can be stable as shown in FIG. 10.

As shown in FIG. 11, when the cutting thickness T is 12 μm, the width at 90% of the maximum value is 1.3 μm, and when the cutting thickness T is not more than 12 μm, the width at 90% of the maximum value is not more than 1.3 μm and not less than 1.1 μm. When the cutting thickness T is more than 12 μm, a change in the width at 90% of the maximum value with respect to the cutting thickness T increases and the width at 90% of the maximum value becomes a value more than 1.3 μm.

In this way, when the cutting thickness T is more than 12 μm, the rigidity of the shaving 13e is large, and the plastic deformation region distributes not only on a side of the shaving 13e but also in the vicinity of the edge portion 30a. Then, a crack 13d is generated at a portion where the stress exceeds the fracture strength, that is, at a portion in the rear of the cutting edge or at a portion in front of the cutting edge as shown in FIG. 8B. However, when the cutting thickness T is not more than 12 μm, the plastic deformation region does not distribute in a large region and a fracture easily occurs at the edge portion 30a of the cutting tool 30. Furthermore, because the cutting process proceeds in a state where a deformation of resin at the peripheral portion of the edge portion 30a is small, a generation of a crack 13d in the cutting surface 13b can be restricted.

When the cutting thickness T is not less than 7 μm, a trace of a plastic deformation, that is, a waved surface is found on a shaving 13e as shown in FIG. 12A. However, when the cutting thickness T is less than 7 μm, a trace of a plastic deformation is not found on a shaving 13e as shown in FIG. 12B. Thus, it is considered that when the cutting thickness T is not less than 7 μm and not more than 12 μm, an elastic deformation region and a plastic deformation region exist, for example, like a region of the strain of 5% to 10% in the stress strain curve shown in FIG. 3. Thus, the cutting thickness T may be not less than 0.5 μm and less than 7 μm.

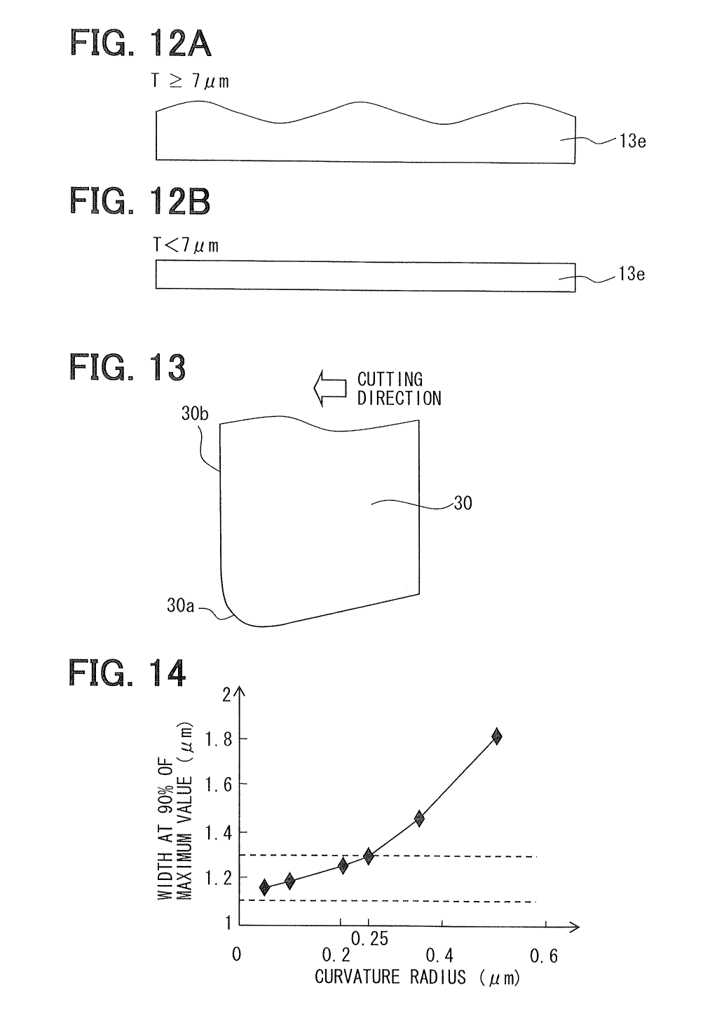

Next, the curvature radius of the edge portion 30a of the cutting tool 30 in the cutting direction will be described. FIG. 13 is a cross-sectional view for explaining the curvature radius of the edge portion 30a of the cutting tool 30. The white arrow in FIG. 13 indicates the cutting direction. FIG. 14 is a graph showing a simulation result of a relationship between the cutting radius of the edge portion 30a in the cutting direction and the width at 90% of the maximum value. In FIG. 14, the upper dashed line indicates the upper limit 1.3 μm and the lower dashed line indicates the rower limit 1.1 μm. As shown in FIG. 14, when the curvature radius of the edge portion 30a is 0.25 μm, the width at 90% of the maximum value is 1.3 μm, and when the curvature radius of the edge portion 30a is not more than 0.25 μm, the width at 90% of the maximum value is not more than 1.3 μm. When the curvature radius is more than 0.25 μm, a change in the width at 90% of the maximum value with respect to the curvature radius increases, and the width at 90% of the maximum value becomes a value more than 1.3 μm.

In addition, when the curvature radius of the edge portion 30a in the cutting direction is more than 0.25 μm, a crack 13d is generated in the cutting surface 13b. This is attributed to the fact that, because the curvature radius is large, the resin insulating layer 13 is extended by the edge portion 30a, the strain becomes large, and the plastic deformation region (the portion applied with the tensile stress) distributes in a large region in the resin insulating layer 13 in the vicinity of the edge portion 30a. Then, at a portion where the stress exceeds the fracture strength, a crack 13d is generated. When the curvature radius is not more than 0.25 μm, a crack 13d is not generated in the cutting surface 13b. This is attributed to the fact that, because the curvature radius is small, the strain due to the extension is small, and the plastic deformation region can be concentrated in a small region in the vicinity of the edge portion 30a.

When the curvature radius decreases, the strain in the resin insulating layer 13 decreases, and furthermore the strength of the cutting tool 30 decreases. Thus, in view of a manufacturing limit, the cutting tool 30 having the curvature radius of not less than 0.03 μm and not more than 0.25 μm may be used.

In the method according to the present embodiment, the portion of the resin insulating layer 13 that has the surface 13c on which the metal layer 15 is disposed is cut in such a manner that, in the stress distribution in the resin insulating layer 13 along the edge portion 30a of the cutting tool 30 and the peripheral portion of the edge portion 30a, the width at 90% of the maximum value is not more than 1.3 μm. Specifically, the cutting tool 30 in which the curvature radius of the edge portion 30a in the cutting direction is not more than 0.25 μm is used, and the resin insulating layer 13 having the extension of more than 0% and not more than 80% is cut by the cutting thickness T of not less than 0.5 μm and not more than 12 μm. Thus, a generation of a crack 13d in the cutting surface 13b can be effectively restricted.

In the point (ii) that the resin insulating layer 13 has the extension of more than 0% and not more than 80%, the point (iii) that the curvature radius of the edge portion 30a of the cutting tool 30 in the cutting direction is not more than 0.25 μm, and the point (iv) that the resin insulating layer 13 is cut by the cutting thickness of not less than 0.5 μm and not more than 12 μm, the cutting process of the portion of the resin insulating layer 13 that has the surface 13c on which the metal layer 15 is disposed may also be performed in such a manner that at least one of the points (ii)-(iv) is satisfied. In such a case, a generation of a crack 13d in the cutting surface 13b can be restricted compared with a case where none of the points (ii)-(iv) is satisfied. When the cutting process is performed in such a manner that two of the points (ii)-(iv) are satisfied, a generation of a crack 13d in the cutting surface 13b can be effectively restricted compared with a case where one of the points (ii)-(iv) is satisfied.

In the method according to the present embodiment, the relative rate of the cutting tool 30 and the semiconductor device 10 is not less than 5 m/s (for example, 20 m/s). When the relative rate is less than 5 m/s, the viscosity of the resin insulating layer 13 cannot be ignored and an influence of the relative rate on cutting is large. When the relative rate is not less than 5 m/s, the viscosity can be almost ignored, and the influence of the relative rate on cutting can be reduced. The upper limit of the relative rate depends of an apparatus limit. For example, when the apparatus limit is 40 m/s, the relative rate may be not less than 5 m/s and not more than 40 m/s.

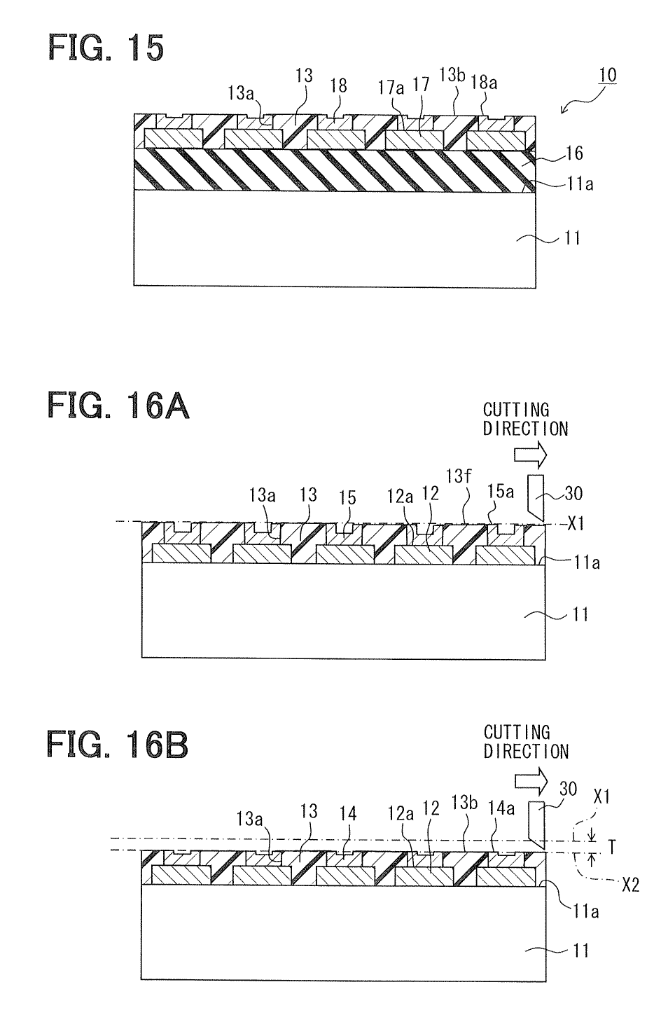

In the manufacturing method according to the present embodiment, the resin insulating layer 13 that covers the front surface 11a of the semiconductor substrate 11 and the underlying electrode 12 is treated with the cutting process. However, the resin insulating layer 13 treated with the cutting process is not limited to the above-described example. The resin insulating layer 13 may be any resin insulating layer included in the semiconductor device 10. For example, the above-described manufacturing method can be applied to the resin insulating layer 13 that covers wiring lines 17 formed on a surface 16a of an insulating layer 16 as shown in FIG. 15. Especially, in the semiconductor device 10 in which a power transistor element such as an IGBT is formed, a thickness of the wiring lines 17 is a few μm, and it is preferred to use the resin insulating layer 13. In FIG. 15, the insulating layer 16 is disposed on the front surface 11a of the semiconductor substrate 11, and the wiring lines 17 are disposed on the surface 16a of the insulating layer 16. The wiring lines 17 are electrically coupled with the semiconductor element in the semiconductor substrate 11 through contact holes (not shown) provided in the insulating layer 16. On the surface 16a of the insulating layer 16, the resin insulating layer 13 is formed so as to cover the wiring lines 17. The resin insulating layer 13 has opening portions 13a so that connection portions of the wiring lines 17 are exposed to an outside of the resin insulating layer 13. In the opening portions 13a, connection parts 18 are formed by patterning a metal layer. In the example shown in FIG. 15, the wiring lines 17 are the uppermost layer wiring, and the connection parts 18 function as pads coupled with an external device. The connection parts 18 can be formed by forming the metal layer so as to cover the surface of the resin insulating layer 13 and removing a portion of the metal layer located outside the opening portions 13a so that a portion of the metal layer located inside the opening portions 13a forms connection parts 18. In the semiconductor device shown in FIG. 10, the underlying electrodes 12 are replaced by the wiring lines 17, the metal electrodes 14 are replaced by the connection parts 18, and the above-described manufacturing method can be applied.

### Second Embodiment

A manufacturing method of a semiconductor device according to a second embodiment of the present invention will be described below. In the manufacturing method according to the present embodiment, (v) a portion of a resin insulating layer 13 that has a surface 13c exposed to an outside is cut by a cutting tool 30 in such a manner that, in a stress distribution in the resin insulating layer 13 along an edge portion 30a of the cutting tool 30 and a peripheral portion of the edge portion 30a, the width at 90% of the maximum value is not more than 0.06 μm. In order to satisfy the point (v), (vi) a resin insulating layer having an extension of more than 0% and not more than 90% is used, (vii) a cutting tool whose edge portion has a curvature radius of not more than 0.35 μm in a cutting direction is used, and (vii) the portion of the resin insulating layer that has the surface 13c exposed to the outside is cut by a cutting thickness of not less than 0.5 μm and not more than 15 μm.

The manufacturing process according to the present embodiment includes a first cutting process shown in FIG. 16A and a second cutting process shown in FIG. 16B.

During the first cutting process shown in FIG. 16A, a portion of the resin insulating layer 13 on which a metal layer 15 is disposed is cut with the cutting tool 30 in a predetermined cutting surface X1 so that a surface portion of the resin insulating layer 15 that has the surface 13c on which the metal layer 15 is disposed is removed with the metal layer 15. The cutting surface X1 is set between the surface 13c of the resin insulating layer 13 and the connection portions 12a of the underlying electrodes 12. By the first cutting process, an exposed surface 13f of the resin insulating layer 13 and an upper surface 15a of the metal layer 15 are located on the same plane. In the first cutting process, the metal layer 15 disposed on the surface 13c of the resin insulating layer 13 may restrict deformation of shavings. Thus, a crack may be generated in the resin insulating layer 13.

During the second cutting process shown in FIG. 16B, a portion of the resin insulating layer 13 in which the surface 13f of the resin insulating layer 13 is exposed and the metal layer 15 located inside the opening portions 13a are cut in a cutting surface X2. Even when a crack is generated during the first cutting process, the crack can be removed by the second cutting process, and the semiconductor device 10 shown in FIG. 10 can be formed. In the present embodiment, a distance between the cutting surfaces X1 and X2, that is, a distance between the surface 13f and the cutting surface 13b of the resin insulating layer 13 is defined as a cutting thickness T of the resin insulating layer 13.

In this way, during the second cutting process, the portion of the resin insulating layer 13 that has the surface 13f exposed to the outside is cut.

The inventors of the present inventions focused on a stress distribution in the resin insulating layer 13 and three parameters that affect the stress in the resin insulating layer 13 when the resin insulating layer 13 is cut, and the inventors carried out the following study in a manner similar to the first embodiment. The three parameters are the extension of the resin insulating layer 13, the cutting thickness of the resin insulating layer 13, and the curvature radius of the edge portion 30a of the cutting tool 30 in the cutting direction.

As the result of the study, a relationship between the width at 90% of the maximum value in the stress distribution and a generation of a crack 13d can be considered as follows. When the width at 90% of the maximum value is more than 0.06 μm, the resin insulating layer 13 is extended at the edge portion 30a of the cutting tool 30, a strain becomes large, and a plastic deformation region (a portion applied with a tensile stress) distributes in a large region in the resin insulating layer 13 in the vicinity of the edge portion 30a. Thus, a crack 13d is generated at a potion where the tensile stress exceeds the fracture strength. When the width at 90% of the maximum value is not more than 0.06 μm, a stain due to the extension is small, and the plastic deformation region can be concentrated in a small region in the vicinity of the edge portion 30a. Thus, a generation of a crack in the cutting surface 13b can be restricted.

In the method according to the present embodiment, the resin insulating layer 13 is cut in such a manner that, in the stress distribution of the resin insulating layer 13 along the edge portion 30a of the cutting tool 30 and the peripheral portion of the edge portion, the width at 90% of the maximum value is not more than 0.06 μm. Thus, when the portion of the resin insulating layer 13 that has the surface 13f exposed to the outside is cut, a generation of a crack 13d in the cutting surface 13b of the resin insulating layer 13 can be restricted. Therefore, in the resin insulating layer 13 after the cutting process, a deterioration of the insulation reliability can be restricted.

A lower limit of the width at 90% of the maximum value depends on manufacturing limits such as a lower limit of the curvature radius of the edge portion 30a of the cutting tool 30 and a lower limit of the cutting thickness. In the present condition, the lower limit of the width at 90% of the maximum value is about 0.04 μm. In view of the above-described point, the resin insulating layer 13 may be cut in such a manner that the width at 90% of the maximum value is within a range from 0.04 μm to 0.06 μm.

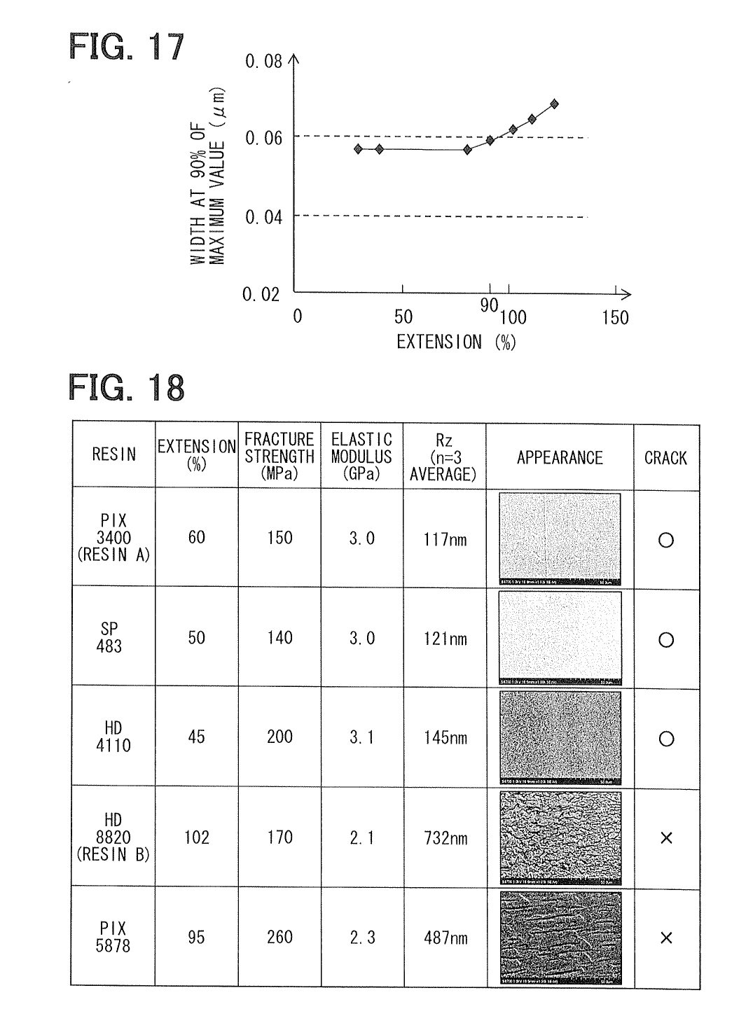

A relationship between the extension of the resin insulating layer 13 and a generation of a crack 13d can be considered as follows. FIG. 17 is a diagram showing a simulation result of a relationship between an extension of resin and the width at 90% of the maximum value. In FIG. 17, the upper dashed line indicates the upper limit 0.06 μm, and the lower dashed line indicates the lower limit 0.04 μm. As shown in FIG. 17, when the extension of resin is 90%, the width at 90% of the maximum value is 0.06 μm, and when the extension is not more than 90%, the width at 90% of the maximum value is substantially constant with respect to the extension. When the extension is more than 90%, the width at 90% of the maximum value increases with the extension, and the width at 90% of the maximum value becomes a value more than 0.06 μm.

In this way, when the extension of the resin insulating layer 13 is more than 90%, because the extension is large, the resin insulating layer 13 is extended without fracturing even when the strain increases. While the resin insulating layer 13 is extended, the stress increases little as shown in FIG. 3, and the plastic deformation region distributes in a large area in the vicinity of the edge portion 30a of the cutting tool 30. Then, a crack 13d is generated at a portion where the stress exceeds the fracture strength, that is, at a portion in the rear of the cutting edge or at a portion in front of the cutting edge as shown in FIG. 8B. In contrast, when the resin insulating layer 13 is made of resin that has an extension more than 0% and not more than 90%, the extension of the resin insulating layer 13 is small. Thus, the plastic deformation region does not distribute in a large area and a fracture occurs at the edge portion 30a of the cutting tool 30. Furthermore, because the cutting process proceeds in a state where a deformation of resin at the peripheral portion of the edge portion 30a is small, a generation of a crack 13d in the cutting surface 13b can be restricted.

Mechanical physical properties and appearance evaluation results of resin materials used as a resin insulating layer are shown in FIG. 18. In the resin materials shown in FIG. 18, PIX3400, HD4110, HD8829, and PIX5878 are polyimide available from HD MicroSystems, and SP483 is polyimide available from Toray Industries, Inc. The extensions and the fracture strengths shown in FIG. 18 are actual measured values. The value Rz means a ten-point average roughness in Japanese Industrial Standard (JIS), and is an average value of mountain-valley three points. The appearance indicates images taken with a SEM, and existence or nonexistence of a crack is evaluated from the images.

As shown in FIG. 18, when a resin insulating layer is made of resin having a small extension such as PIX3400, SP483, and HD4110, the value Rz is small (about 100 nm to 150 nm), and a crack is not found in the SEM images. In contrast, when a resin insulating layer is made of resin having a large extension such as HD8820 and PIX5878, the value Rz is large (more than 450 nm) and a crack is found in the SEM images. Also from results not shown, when a resin insulating layer has an extension of not more than 90%, a crack is not found in a cutting surface. Thus, resin material having an extension of not more than 90% can be suitably used for the resin insulating layer 13.

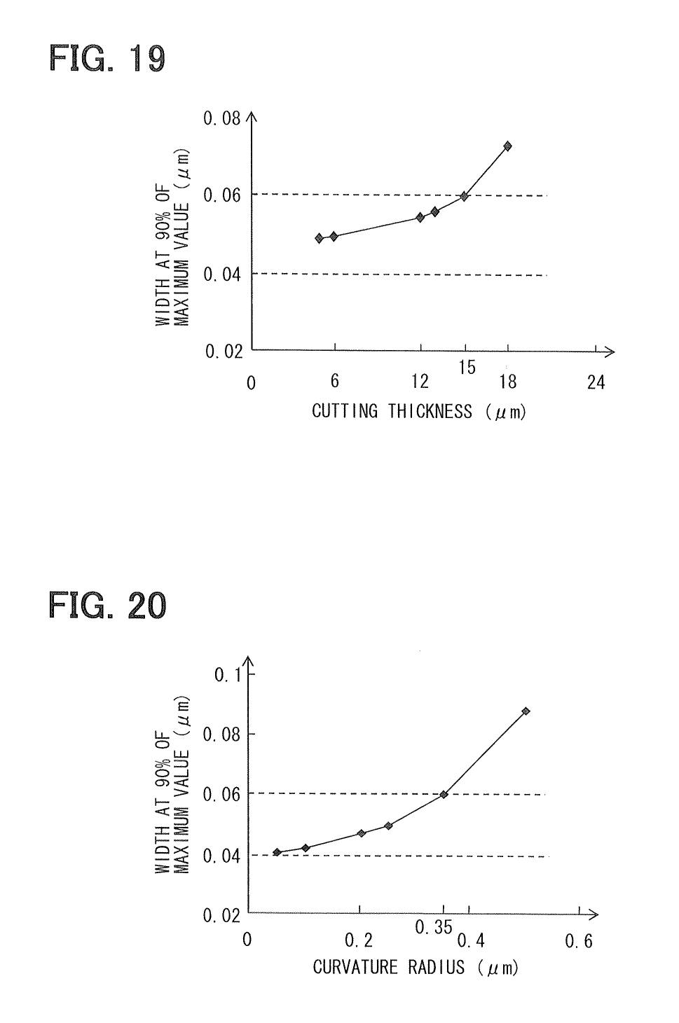

Next, the cutting thickness T of the resin insulating layer 13 with the cutting tool 30 will be described below. FIG. 19 is a graph showing a simulation result of a relationship between the cutting thickness T and the width at 90% of the maximum value. In FIG. 19, the upper dashed line indicates the upper limit 0.06 μm, and the lower dashed line indicates the lower limit 0.04 μm.

In a manner similar to the first embodiment, when the cutting thickness T is less than 0.5 μm, the thickness of the resin insulating layer 13 is so thin that the edge portion 30a of the cutting tool 30 does not bit the resin insulating layer 13, and the cutting thickness T may be not stable. In contrast, when the cutting thickness T is not less than 0.5 μm, the cutting thickness T can be stable as shown in FIG. 10.

As shown in FIG. 19, when the cutting thickness T is 15 μm, the width at 90% of the maximum value is 0.06 μm, and when the cutting thickness T is not more than 15 μm, the width at 90% of the maximum value is not more than 0.06 μm and not less than 0.04 μm. When the cutting thickness T is more than 15 μm, a change in the width at 90% of the maximum value with respect to the cutting thickness T increases and the width at 90% of the maximum value becomes a value more than 0.06 μm.

In this way, when the cutting thickness T is more than 15 μm, the rigidity of the shaving 13e is large, and the plastic deformation region distributes not only on a side of the shaving 13e but also in the vicinity of the edge portion 30a of the cutting tool 30. Then, at a portion where the stress exceeds the fracture strength, a crack 13d is generated. However, when the cutting thickness T is not more than 15 μm, the plastic deformation region does not distribute in a large region and a fracture easily occurs at the edge portion 30a of the cutting tool 30. Furthermore, because the cutting process proceeds in a state where a deformation of resin at the peripheral portion of the edge portion 30a is small, a generation of a crack 13d in the cutting surface 13b can be restricted.

Although they are not shown, when the cutting thickness T is not less than 8 μm, a trace of a plastic deformation, that is, a waved surface is found on a shaving 13e, and when the cutting thickness T is less than 8 μm, a trace of a plastic deformation is not found on a shaving 13e. Thus, in a manner similar to the first embodiment, it is considered that when the cutting thickness T is not less than 8 μm and not more than 15 μm, an elastic deformation region and a plastic deformation region exist, for example, like a region of the strain of 5% to 10% in the stress strain curve shown in FIG. 3. Thus, the cutting thickness may be not less than 0.5 μm and less than 8 μm.

Next, the curvature radius of the edge portion 30a of the cutting tool 30 in the cutting direction will be described. FIG. 20 is a graph showing a simulation result of a relationship between the curvature radius of the edge portion 30a of the cutting tool 30 in the cutting direction and the width at 90% of the maximum value. In FIG. 20, the upper dashed line indicates the upper limit 0.06 μm, and the lower dashed line indicates the lower limit 0.04 μm. As shown in FIG. 20, when the curvature radius of the edge portion 30a is 0.35 μm, the width at 90% of the maximum value is 0.06 μm, and when the curvature radius of the edge portion 30a is not more than 0.35 μm, the width at 90% of the maximum value is not more than 0.06 μm. When the curvature radius is more than 0.35 μm, a change in the width at 90% of the maximum value with respect to the curvature radius increases, and the width at 90% of the maximum value becomes a value more than 0.06 μm.

In addition, when the curvature radius of the edge portion 30a in the cutting direction is more than 0.35 μm, a crack 13d is generated in the cutting surface 13b. This is attributed to the fact that, because the curvature radius is large, the resin insulating layer 13 is extended by the edge portion 30a, the strain becomes large, the plastic deformation region (the portion applied with the tensile stress) distributes in a large region in the resin insulating layer 13 in the vicinity of the edge portion 30a. Then, at a portion where the stress exceeds the fracture strength, a crack 13d is generated. When the curvature radius is not more than 0.35 μm, a crack 13d is not generated in the cutting surface 13b. This is attributed to the fact that, because the curvature radius is small, the strain due to extension is small, and the plastic deformation region can be concentrated in a small region in the vicinity of the edge portion 30a.

Because of a manufacturing limit, the lower limit of the curvature radius is about 0.03 μm. Thus, in view of the manufacturing limit, the cutting tool 30 having the curvature radius of not less than 0.03 μm and not more than 0.35 μm may be used.

In the method according to the present embodiment, the portion of the resin insulating layer 13 that has the surface 13f exposed to the outside is cut in such a manner that, in the stress distribution in the resin insulating layer 13 along the edge portion 30a of the cutting tool 30 and the peripheral portion of the edge portion 30a, the width at 90% of the maximum value is not more than 0.06 μm. Specifically, the cutting tool 30 whose the edge portion 30a has the curvature radius of not more than 0.35 μm in the cutting direction is used, and the resin insulating layer 13 having the expansion of more than 0% and not more than 90% is cut by the cutting thickness T of not less than 0.5 μm and not more than 15 μm. Thus, a generation of a crack 13d in the cutting surface 13b can be effectively restricted.

In the point (vi) that the resin insulating layer 13 has the expansion of more than 0% and not more than 90%, the point (vii) that the curvature radius of the edge portion 30a of the cutting tool 30 in the cutting direction is not more than 0.35 μm, and the point (viii) that the resin insulating layer 13 is cut by the cutting thickness of not less than 0.5 μm and not more than 15 μm, the cutting process of the portion of the resin insulating layer 13 that has the surface 13f exposed to the outside may also be performed in such a manner that at least one of the points (vi)-(viii) is satisfied. In such a case, a generation of a crack 13d in the cutting surface 13b can be restricted compared with a case where none of the points (vi)-(viii) is satisfied. When the cutting process is performed in such a manner that two of the points (vi)-(vii) is satisfied, a generation of a crack 13d in the cutting surface 13b can be effectively restricted compared with a case where one of the points (vi)-(viii) is satisfied.

The semiconductor device 10 shown in FIG. 15 may also be manufactured by the method according to the present embodiment.

The semiconductor device 10 may also be manufactured by a method different from the above-described method including the first cutting process and the second cutting process.

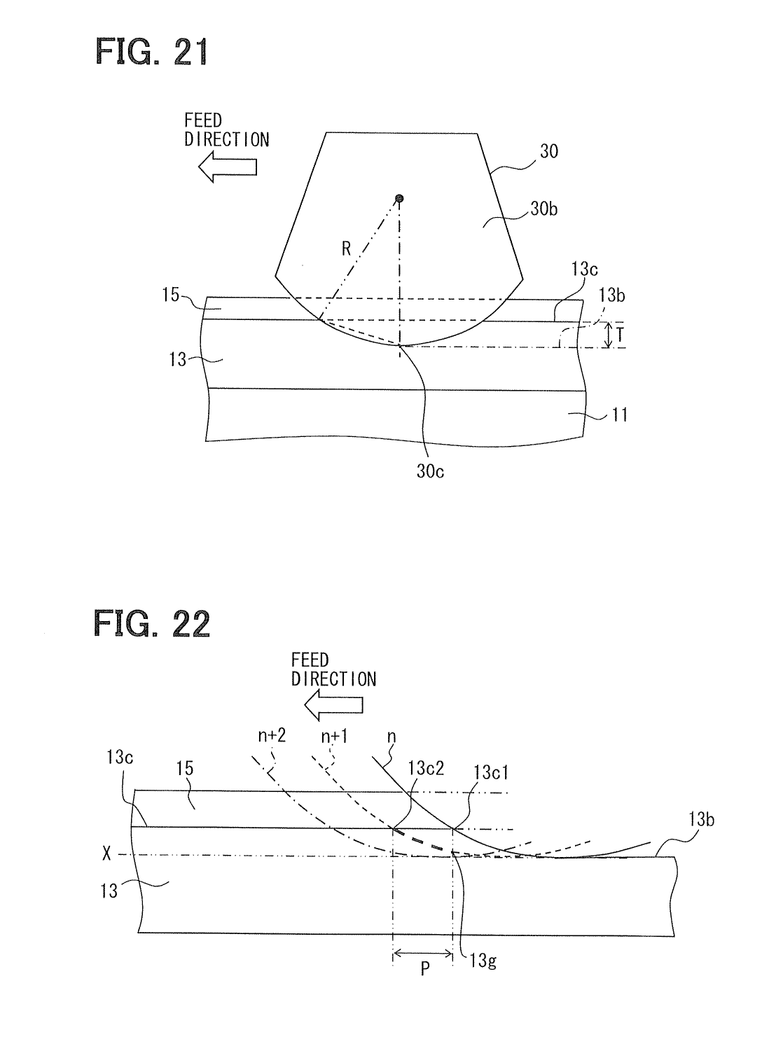

A cutting tool 30 shown in FIG. 21 includes a first edge portion and a second edge portion at an edge of a front surface 30b. The first edge portion extends from an edge point 30c of the cutting tool 30 forward in a pitch feed direction shown by the white arrow in FIG. 21. The second edge portion extends from the edge point 30c backward in the pitch feed direction. In other words, the cutting tool 30 has an arc edge in which the first edge portion and the second edge portion are connected, and the arc edge has a curvature radius R. A portion of the resin insulating layer 13 that has a surface on which the metal layer 15 is disposed is cut with the cutting tool 30 in a cutting surface X described in the first embodiment (see FIG. 2B). A cross-section of the metal layer 15 and the resin insulating layer 13 which are cut with the cutting tool 30 have a shape cut with a part of arc having the curvature radius R.

As shown in FIG. 22, when an nth cutting is performed, the metal layer 15 remains on the left of a point 13c1 by cutting with the first edge portion of the cutting tool 30. In the resin insulating layer 13, a portion located on the right of the point 13c1 and located under a cutting surface of the nth cutting shown by the solid arc in FIG. 22 is exposed to an outside. In other words, by the cutting with the first edge portion, a surface of a portion of the resin insulating layer 13 is exposed to the outside.

Next, as shown in FIG. 2s, the cutting tool 30 is moved by a predetermined pitch P in the pitch feed direction, and an (n+1)th cutting is performed. By cutting with the first edge portion of the cutting tool 30, the metal layer 15 remains on the left of a point 13c2. In the resin insulating layer 13, a portion located on the right of the point 13c2 and located under a cutting surface of the (n+1)th cutting shown by the dashed arc in FIG. 22 is exposed to the outside. The whole area of the portion of the resin insulating layer 13 that has the surface exposed to the outside by the nth cutting is cut off by the (n+1)th cutting. In the (n+1)th cutting, the metal layer 15 disposed on the surface 13c of the resin insulating layer 13 restricts deformation of a shaving. Thus, a crack may be easily generated in the resin insulating layer 13. When an intersection of a perpendicular line extending from the point 13c1 and the cutting surface of the (n+1)th cutting is expressed by a point 13g, the crack may be generated in a partial arc connecting the point 13g and the point 13c2.

When the cutting tool 30 is moved by the predetermined pitch P in the pitch feed direction and an (n+2)th cutting is performed, the partial arc connecting the point 13g and the point 13c2 is cut. A cutting surface of the (n+2)th cutting is shown by the dashed-dotted line in FIG. 22. The cutting tool 30 and the predetermined pitch P can be set, for example, in a manner described in the patent document 4. The pitch feed direction is perpendicular to the cutting direction of the cutting tool 30. In FIG. 21, the cutting direction is perpendicular to the paper.

By repeating the cutting with the cutting tool 30 while moving the cutting tool 30 by the predetermined pitch P in the pitch feed direction, the semiconductor device 10 can be formed. In the present modification, a portion of the resin insulating layer 13 that has the surface 13c on which the metal layer 15 is disposed is cut and a surface of a portion of the resin insulating layer 13 is exposed by the first edge portion, and the portion of the resin insulating layer 13 having the exposed surface is removed with the cutting tool 30 when the cutting tool 30 is moved in the pitch feed direction. Thus, the cutting direction can be simplified and a cutting time can be reduced.

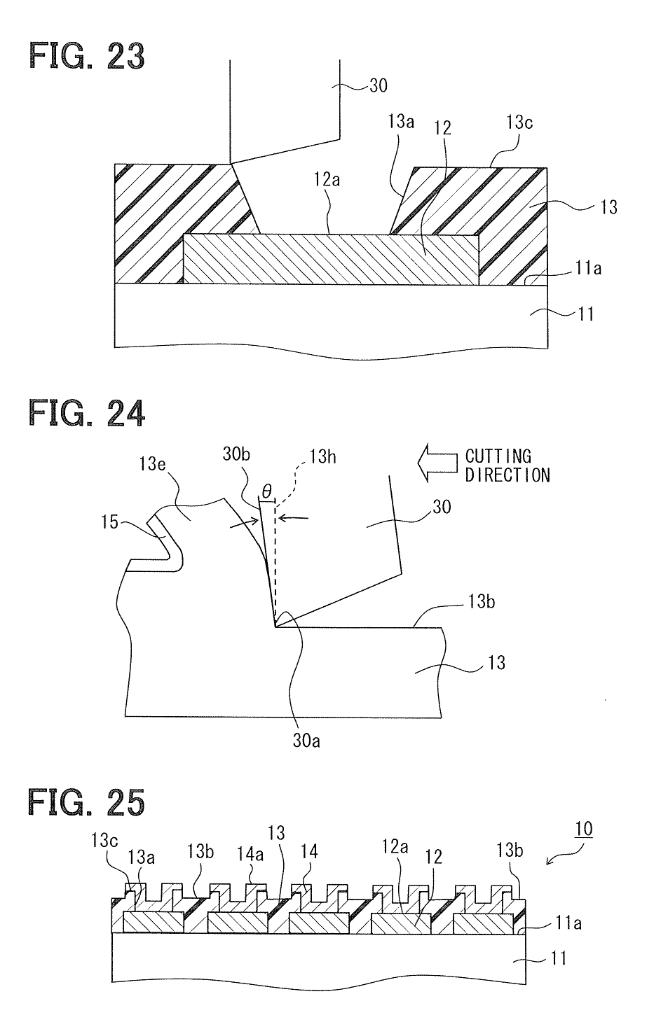

In the method according to the present embodiment, the resin insulating layer 13 is treated with the cutting process so that the metal layer 15 is treated with a patterning process and the metal electrodes 14 or the connection parts 18 are formed. However, the above-described method may also be applied when the opening portions 13a are provided in the resin insulating layer 13 by a cutting process with the cutting tool 30 as shown in FIG. 23. Also in this case, a portion of the resin insulating layer 13 having an exposed surface is cut. Thus, a generation of a crack in a wall (cutting surface) of the opening portion 13a can be restricted.

### Other Embodiments

Although the present invention has been fully described in connection with the exemplary embodiments thereof with reference to the accompanying drawings, it is to be noted that various changes and modifications will become apparent to those skilled in the art.

In the above-described embodiments, a front rake θ of the cutting tool 30 is not mentioned. As shown in FIG. 24, the front rake θ of the cutting tool 30 may be 0 degree or a negative angle. For example, the front rake θ may be within a range from −15 degrees to 0 degree. The front rake θ is defined as an angle between the front surface 30b of the cutting tool 30 and a plane 13h perpendicular to the cutting surface 13b. In an example shown in FIG. 24, the front rake θ is a negative angle. When the cutting tool 30 is tilted forward, a compressing stress field is provided in the resin insulating layer 13 in the vicinity of the edge portion 30a of the cutting tool 30, and the tensile stress can be offset compared with a case where the front rake θ of the cutting tool 30 is a positive angle. In addition, a region applied with the tensile stress, that is, a plastic deformation region can be small. Thus, a generation of a crack 13d in the cutting surface 13b can be restricted.

In the above-described embodiments, the resin insulating layer 13 is made of polyimide as an example. The resin insulating layer 13 may be made of any resin that is suitable for securing electric insulation in the semiconductor device 10 and has a predetermined extension. In a case where the metal layer 15 is disposed on the surface of the resin insulating layer 13, the predetermined extension is more than 0% and not more than 80%. In a case where the surface of the resin insulating layer 13 is exposed to the outside, the predetermined extension is more than 0% and not more than 90%.

In the above-described embodiments, the metal electrodes 14 are located only inside the opening portion 13a and have recess portions on the surfaces thereof. The arrangement of the metal electrodes 14 is not limited to the above-described example. For example, the metal electrodes 14 may not have the recess portions on the surfaces thereof and the surfaces of the metal electrodes 14 may be flat. Also in the present case, because the metal layer 15 disposed on the surface 13c of the resin insulating layer 13 can be removed with the surface portion of the resin insulating layer 13, the manufacturing process can be simplified. The metal electrodes 14 may also be located around the opening portions 13a on the surface 13c of the resin insulating layer 13 as shown in FIG. 25. In the present case, the semiconductor device 10 can be formed by cutting only a portion of the surface 13c of the resin insulating layer 13 corresponding to the cutting surface 13b. In the semiconductor device 10 shown in FIG. 25, a contact surface between the metal electrodes 14 and connection members such as solder can be increased compared with the semiconductor device 10 shown in FIG. 1. However, because portions where the metal electrodes 14 are disposed are not cut, a cutting time may increase.

What is claimed is:

1. A method of manufacturing a semiconductor device comprising
cutting a part of a resin insulating layer formed on a surface of a semiconductor substrate with a cutting tool, wherein
the cutting the part of the resin insulating layer includes cutting a portion of the resin insulating layer that has a surface on which a metal layer is disposed, and
the cutting the portion of the resin insulating layer is performed in such a manner that, in a stress distribution inside the resin insulating layer along an edge portion of the cutting tool and a peripheral portion of the edge portion, a width at 90% of a maximum value is not more than 1.3 μm.

2. The method according to claim 1, wherein:
the edge portion of the cutting tool has a curvature radius of not more than 0.25 μm in a cutting direction;
the resin insulating layer has an extension of more than 0% and not more than 80%; and
the portion of the resin insulating layer is cut by a cutting thickness of not less than 0.5 μm and not more than 12 μm.

3. The method according to claim 1, wherein
the resin insulating layer has an extension of more than 0% and not more than 80%, and
the portion of the resin insulating layer is cut by a cutting thickness of not less than 0.5 μm and not more than 12 μm.

4. The method according to claim 1, wherein
the edge portion of the cutting tool has a curvature radius of not more than 0.25 μm in a cutting direction, and
the resin insulating layer has an extension of more than 0% and not more than 80%.

5. The method according to claim 1, wherein
the edge portion of the cutting tool has a curvature radius of not more than 0.25 μm in a cutting direction, and
the portion of the resin insulating layer is cut by a cutting thickness of not less than 0.5 μm and not more than 12 μm.

6. The method according to claim 1, wherein
the edge portion of the cutting tool has a curvature radius of not more than 0.25 μm in a cutting direction.

7. The method according to claim 1, wherein
the resin insulating layer has an extension of more than 0% and not more than 80%.

8. The method according to claim 1, wherein
the portion of the resin insulating layer is cut by a cutting thickness of not less than 0.5 μm and not more than 12 μm.

9. The method according to claim 8, wherein
the portion of the resin insulating layer is cut by a cutting thickness of not less than 0.5 μm and less than 7 μm.

10. The method according to claim 1, wherein
the cutting the part of the resin insulating layer includes setting a relative rate of the cutting tool and the semiconductor substrate to a value not less than 5 m/s.

11. The method according to claim 1, wherein
the cutting the part of the resin insulating layer includes setting a front rake of the cutting tool to 0 degree or a negative angle.

12. The method according to claim 1, further comprising:
forming an underlying electrode on the surface of the semiconductor substrate, the underlying electrode electrically coupled with a semiconductor element formed in the semiconductor substrate;
forming the resin insulating layer on the surface of the semiconductor substrate so as to cover the underlying electrode;
providing an opening portion in the resin insulating layer so that a connection portion of the underlying electrode is exposed to an outside of the resin insulating layer through the opening portion; and
forming the metal layer covering the surface of the resin insulating layer and a surface of the connection portion of the underlying electrode exposed through the opening portion, wherein
the cutting the part of the resin insulating layer is performed after the forming the metal layer, and
the cutting the part of the resin insulating layer includes removing a portion of the metal layer located outside the opening portion so that a portion of the metal layer located inside the opening portion forms a metal electrode.

13. The method according to claim 1, further comprising:
forming an insulating layer on the surface of the semiconductor substrate;
forming a wiring line on a surface of the insulating layer;
forming the resin insulating layer on the surface of the insulating layer so as to cover the wiring line;
providing an opening portion in the resin insulating layer so that a connection portion of the wiring line is exposed to an outside of the resin insulating layer through the opening portion; and
forming the metal layer covering the surface of the resin insulating layer and a surface of the connection portion of the wiring line exposed through the opening portion, wherein
the cutting the part of the resin insulating layer is performed after the forming the metal layer, and
the cutting the part of the resin insulating layer includes removing a portion of the metal layer located outside the opening portion so that a portion of the metal layer located inside the opening portion forms a connection part.

14. A method of manufacturing a semiconductor device comprising
cutting a part of a resin insulating layer formed on a surface of a semiconductor substrate with a cutting tool, wherein
the cutting the part of the resin insulating layer includes cutting a portion of the resin insulating layer that has a surface exposed to an outside, and
the cutting the portion of the resin insulating layer is performed in such a manner that, in a stress distribution inside the resin insulating layer along an edge portion of the cutting tool and a peripheral portion of the edge portion, a width at 90% of a maximum value is not more than 0.06 μm.

15. The method according to claim 14, wherein:
the edge portion of the cutting tool has a curvature radius of not more than 0.35 μm in a cutting direction;
the resin insulating layer has an extension of more than 0% and not more than 90%; and
the portion of the resin insulating layer is cut by a cutting thickness of not less than 0.5 μm and not more than 15 μm.

16. The method according to claim 14, wherein
the resin insulating layer has an extension of more than 0% and not more than 90%; and
the portion of the resin insulating layer is cut by a cutting thickness of not less than 0.5 μm and not more than 15 μm.

17. The method according to claim 14, wherein
the edge portion of the cutting tool has a curvature radius of not more than 0.35 μm in a cutting direction, and
the resin insulating layer has an extension of more than 0% and not more than 90%.

18. The method according to claim 1, wherein
the edge portion of the cutting tool has a curvature radius of not more than 0.35 μm in a cutting direction, and
the portion of the resin insulating layer is cut by a cutting thickness of not less than 0.5 μm and not more than 15 μm.

19. The method according to claim 14, wherein
the edge portion of the cutting tool has a curvature radius of not more than 0.35 μm in a cutting direction.

20. The method according to claim 14, wherein
the resin insulating layer has an extension of more than 0% and not more than 90%.

21. The method according to claim 14, wherein
the portion of the resin insulating layer is cut by a cutting thickness of not less than 0.5 μm and not more than 15 μm.

22. The method according to claim 21, wherein
the portion of the resin insulating layer is cut by a cutting thickness of not less than 0.5 μm and less than 8 μm.

23. The method according to claim 14, wherein
the cutting the part of the resin insulating layer includes setting a relative rate of the cutting tool and the semiconductor substrate to a value not less than 5 m/s.

24. The method according to claim 14, wherein
the cutting the part of the resin insulating layer includes setting a front rake of the cutting tool to 0 degree or a negative angle.

25. The method according to claim 14, wherein
the cutting the part of the resin insulating layer further includes removing a surface portion of the resin insulating layer with a metal layer disposed on the surface portion before the cutting the portion of the resin insulating layer that has the surface exposed to the outside.

26. The method according to claim 25, wherein the cutting the part of the resin insulating layer includes
cutting the surface portion of the resin insulating layer on which the metal layer is disposed with the cutting tool so that the surface of the portion of the resin insulating layer is exposed to the outside, and
after moving the cutting tool by a predetermined pitch in a pitch feed direction, cutting the portion of the resin insulating layer that has the surface exposed to the outside with the cutting tool.

27. The method according to claim 25, further comprising:
forming an underlying electrode on the surface of the semiconductor substrate, the underlying electrode electrically coupled with a semiconductor element formed in the semiconductor substrate;
forming the resin insulating layer on the surface of the semiconductor substrate so as to cover the underlying electrode;
providing an opening portion in the resin insulating layer so that a connection portion of the underlying electrode is exposed to an outside of the resin insulating layer through the opening portion; and
forming the metal layer covering the surface of the resin insulating layer and a surface of the connection portion of the underlying electrode exposed through the opening portion, wherein
the cutting the part of the resin insulating layer is performed after the forming the metal layer, and
the cutting the part of the resin insulating layer includes removing a portion of the metal layer located outside the opening portion so that a portion of the metal layer located inside the opening portion forms a metal electrode.

28. The method according to claim 25, further comprising:
forming an insulating layer on the surface of the semiconductor substrate;
forming a wiring line on a surface of the insulating layer;
forming the resin insulating layer on the surface of the insulating layer so as to cover the wiring line;
providing an opening portion in the resin insulating layer so that a connection portion of the wiring line is exposed to an outside of the resin insulating layer through the opening portion; and
forming the metal layer covering the surface of the resin insulating layer and a surface of the connection portion of the wiring line exposed through the opening portion, wherein
the cutting the part of the resin insulating layer is performed after the forming the metal layer, and
the cutting the part of the resin insulating layer includes removing a portion of the metal layer located outside the opening portion so that a portion of the metal layer located inside the opening portion forms a connection part.
